(19) United States
(12) Patent Application Publication
(10) Pub. No.: US 2014/0019075 A1
(43) Pub. Date: Jan. 16, 2014

(54) MEASUREMENT SYSTEM FOR MEASURING INDUCTANCE

(71) Applicants: YUN BAI, Shenzhen City (CN); PENG CHEN, Shenzhen City (CN); SONG-LIN TONG, Shenzhen City (CN)

(72) Inventors: YUN BAI, Shenzhen City (CN); PENG CHEN, Shenzhen City (CN); SONG-LIN TONG, Shenzhen City (CN)

(21) Appl. No.: 13/628,072

(22) Filed: Sep. 27, 2012

(30) Foreign Application Priority Data
Jul. 12, 2012 (CN) 2012102403258

(51) Int. Cl. G01R 27/26; G06F 19/00

(52) U.S. Cl. 702/65

(57) ABSTRACT

A measurement system includes a control circuit, a measurement circuit, and a display circuit. The measurement circuit includes a first capacitor. The control circuit outputs control signals to control first or second inductors and the first capacitor to compose an LC circuit. Inductance can be gained according to the formula:

$$L = \frac{1}{4 π \cdot {f}^{2} \cdot C} ,$$

where L stands for the inductance, f stands for a frequency of the LC circuit, π stands for ratio of a circle's circumference to its diameter, and C stands for capacitance of the first capacitor. The control circuit also controls the first and second inductors to be connected in parallel and then connected in parallel to the first capacitor to compose an LC circuit, to determine a coupling inductance. A leak inductance is equal to a half of the coupling inductance. The display circuit displays the inductances of the first and second inductors and the leak inductance.

### BACKGROUND

1. Technical Field

The present disclosure relates to measurement systems, and particularly to a measurement system for measuring inductance.

2. Description of Related Art

Inductors are widely used in voltage regulators of motherboards. Inductance of the inductors is generally measured by manual operation. This is a time-consuming and inconvenient operation.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present embodiments.

FIG. 1 is a block diagram of a measurement system for inductance in accordance with an exemplary embodiment of the present disclosure, wherein the measurement system includes a control circuit, a measurement circuit, and a display circuit.

FIG. 2 is a circuit diagram of the control circuit of FIG. 1.

FIG. 3 and FIG. 4 are circuit diagrams of the measurement circuit of FIG. 1.

FIG. 5 is a circuit diagram of the display circuit of FIG. 1.

### DETAILED DESCRIPTION

The disclosure, including the drawing, is illustrated by way of example and not by way of limitation. References to “an” or “one” embodiment in this disclosure are not necessarily to the same embodiment, and such references mean at least one.

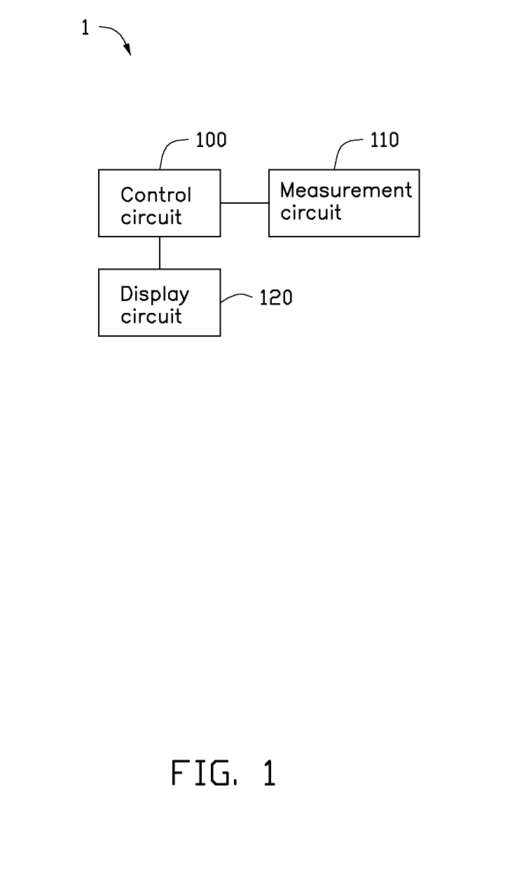

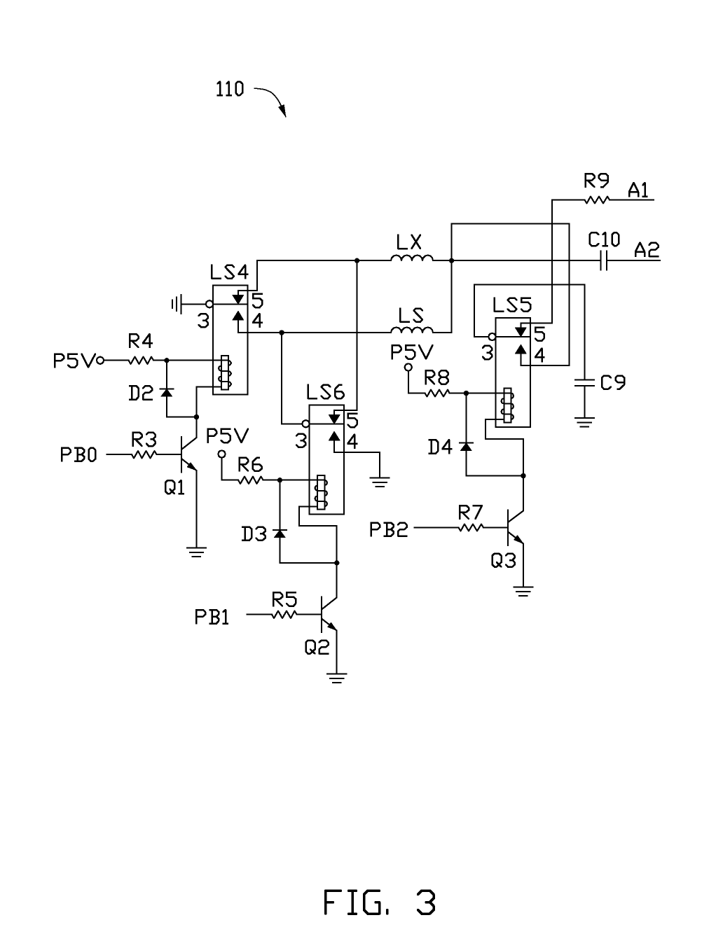

Referring to FIGS. 1 and 3, a measurement system 1 in accordance to an exemplary embodiment is shown. The measuring system 1 is used for measuring inductance of first and second inductors Ls and Lx. The measurement system 1 includes a control circuit 100, a measurement circuit 110, and a display circuit 120. The measurement circuit 110 comprises a capacitor C9.

The control circuit 100 is connected to the measurement circuit 110, to control the first inductor Ls or the second inductor Lx and the capacitor C9 to compose an LC circuit. The control circuit 100 receives a frequency from the LC circuit, to gain the inductance L according to a formula:

$$L = \frac{1}{4 π \cdot {f}^{2} \cdot C 9} ,$$

where L stands for inductance of the first inductor Ls or the second inductor Lx, π stands for the ratio of a circle's circumference to its diameter, f stands for a frequency output from the LC circuit, and C9 stands for capacitance of the capacitor C9. The first inductor Ls and the second inductor Lx are connected in parallel, and then connected in parallel to the capacitor C9, to compose an LC circuit. Thus, a leak inductance Lk of the first inductor Ls and the second inductor Lx connected in parallel is equal to L/2.

The display circuit 120 is connected to the control circuit 100, to display the inductance of the first inductor Ls, the inductance of the second inductor Lx, and the leak inductance Lk of the first inductor Ls and the second inductor Lx connected in parallel.

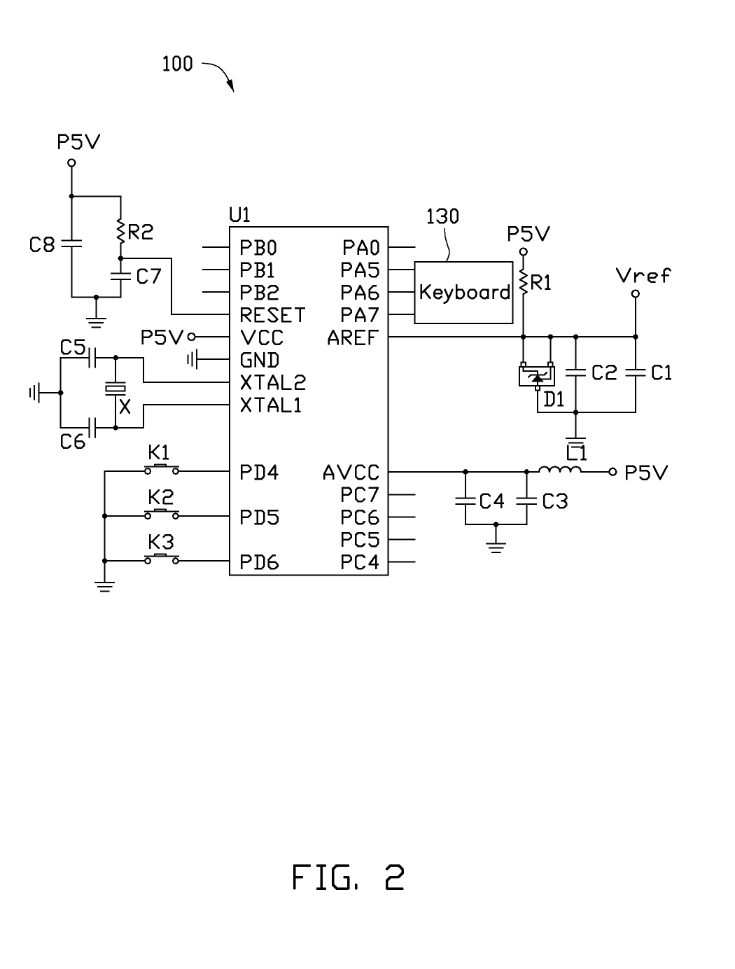

Referring to FIG. 2, the control circuit 100 of the embodiment is shown. The control circuit 100 includes a microcontroller U1. A first group of input output (I/O) pins PB0-PB2 of the microcontroller U1 are configured to output control signals. A pin PA0 of a second group of I/O pins of the microcontroller U1 is connected to the measurement circuit 110. Pins PA5-PA7 of the second group of I/O pins of the microcontroller U1 are connected to a keyboard 130. A power pin AREF of the microcontroller U1 is connected to a power source P5V through a resistor R1 and also connected to a cathode and a control terminal of a voltage regulating diode D1. An anode of the voltage regulating diode D1 is grounded. The power pin AREF of the microcontroller U1 is also connected to a power source Vref. Capacitors C1 and C2 are connected in parallel between the control terminal and the anode of the voltage regulating diode D1. A power pin AVCC of the microcontroller U1 is connected to the power source P5V through an inductor L1. Capacitors C3 and C4 are connected in parallel between the power pin AVCC of the microcontroller U1 and ground.

A third group of I/O pins PC4-PC7 of the microcontroller U1 are connected to the display circuit 120. A fourth group of I/O pins PD4-PD6 of the microcontroller U1 are grounded through switches K1-K3, respectively. Clock pins XTAL1 and XTAL2 of the microcontroller U1 are connected to two ends of a crystal oscillator X. The two ends of the crystal oscillator X are grounded through capacitors C5 and C6, respectively. A power pin VCC of the microcontroller U1 is connected to the power source P5V. A reset pin RESET of the microcontroller U1 is connected to the power source P5V through a resistor R2 and also grounded through a capacitor C7. A capacitor C8 is connected between the power source P5V and ground.

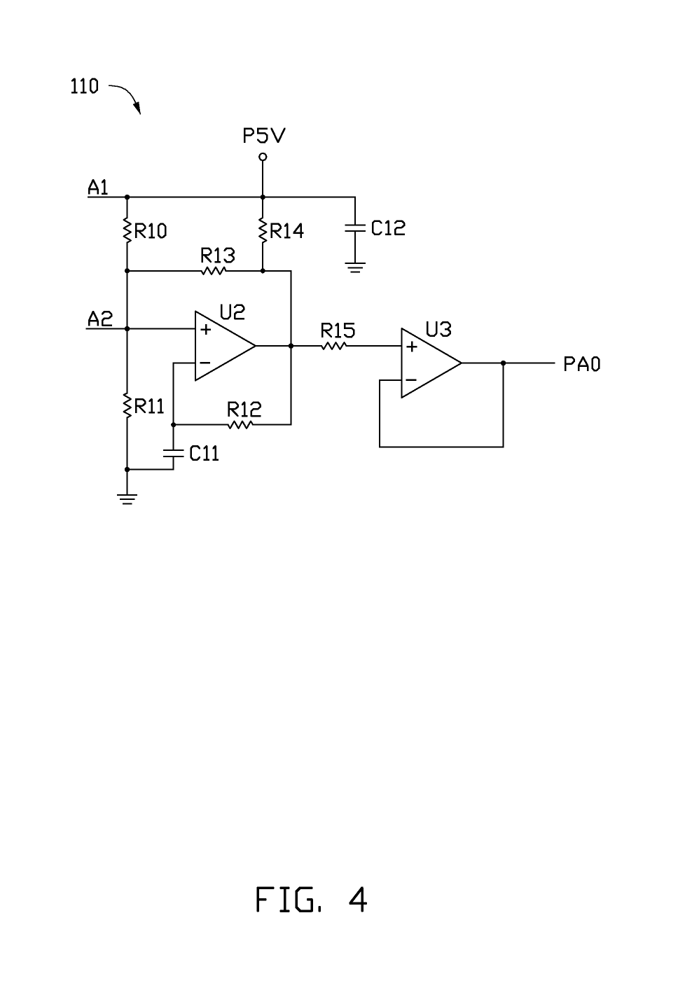

Referring to FIGS. 3 and 4, the measurement circuit 110 of the embodiment is shown. The measurement circuit 110 includes transistors Q1-Q3, relays LS4-LS6, and comparators U2 and U3. A base of the transistor Q1 is connected to the pin PB0 of the microcontroller U1 through a resistor R3. In the embodiment, the transistors Q1-Q3 are npn transistors. An emitter of the transistor Q1 is grounded. A collector of the transistor Q1 is connected to a first end of the coil of the relay LS4 and an anode of a diode D2. A second end of the coil of the relay LS4 is connected to a cathode of the diode D2. The cathode of the diode D2 is also connected to the power source P5V through a resistor R4. A fixing contact 3 of the switch of the relay LS4 is grounded. A moving contact 4 of the switch of the relay LS4 is connected to the fixing contact 3 of the switch of the relay LS6. A moving contact 4 of the switch of the relay LS6 is grounded. A moving contact 5 of the switch of the relay LS6 is connected to the moving contact 5 of the switch of the relay LS4.

A base of the transistor Q2 is connected to the pin PB1 of the microcontroller U1 through a resistor R5. An emitter of the transistor Q2 is grounded. A collector of the transistor Q2 is connected to a first end of the coil of the relay LS6 and an anode of a diode D3. A second end of the coil of the relay LS6 is connected to a cathode of the diode D3. The cathode of the diode D3 is also connected to the power source P5V through a resistor R6.

The moving contact 4 of the switch of the relay LS4 is also connected to a first end of the second inductor Lx through the first inductor Ls. A second end of the second inductor Lx is connected to the moving contact 5 of the switch of the relay LS4.

A base of the transistor Q3 is connected to the pin PB2 of the microcontroller U1 through a resistor R7. An emitter of the transistor Q3 is grounded. A collector of the transistor Q3 is connected to a first end of the coil of the relay LS5 and an anode of a diode D4. A second end of the coil of the relay LS5 is connected to a cathode of the diode D4. The cathode of the diode D4 is also connected to the power source P5V through a resistor R8.

A fixing contact 3 of the switch of the relay LS5 is grounded through the capacitor C9. A moving contact 4 of the switch of the relay LS5 is connected to the first end of the inductor Lx. A moving contact 5 of the switch of the relay LS5 is connected to a non-inverting input terminal of the comparator U2 through resistors R9 and R10 connected in series. The non-inverting input terminal of the comparator U2 is also connected to the first end of the inductor Lx through a capacitor C10. The non-inverting input terminal of the comparator U2 is further grounded through a resistor R11. An inverting input terminal of the comparator U2 is grounded through a capacitor C11 and also connected to an output terminal of the comparator U2 through a resistor R12. The output terminal of the comparator U2 is connected to the non-inverting input terminal of the comparator U2 through a resistor R13. The output terminal of the comparator U2 is also connected to the power source P5V through a resistor R14. A capacitor C12 is connected between the power source P5V and ground.

A non-inverting input terminal of the comparator U3 is connected to the output terminal of the comparator U2 through a resistor R15. An inverting input terminal of the comparator U3 is connected to an output terminal of the comparator U3 and the pin PA0 of the microcontroller U1.

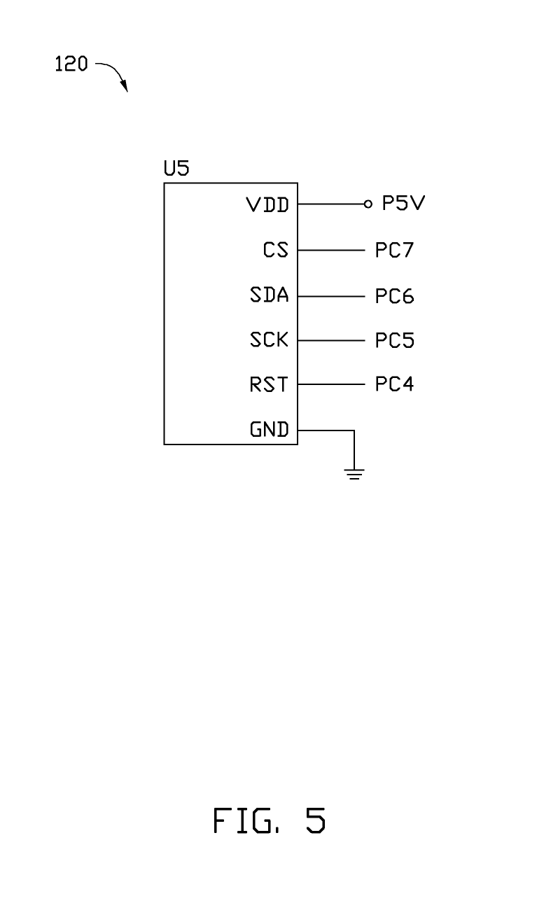

Referring to FIG. 5, the display circuit 120 includes a display screen U5. A power pin VDD of the display screen U5 is connected to the power source P5V. Data pins CS, SDA, SCK, and RST of the display screen U5 are respectively connected to the pins PC7, PC6, PC5, and PC4 of the microcontroller U1. A ground pin GND of the display screen U5 is grounded.

In use, the microcontroller U1 receives input signals from the keyboard 130 and the switches K1-K3 respectively through the pins PA5-PA7 and PD4-PD6, and outputs control signals to the transistors Q1-Q3 of the measurement circuit 110 through the pins PB0-PB2 according to the received input signals.

When the inductance of the second inductor Lx needs to be measured, the microcontroller U1 receives a first input signal from the keyboard 130, and the pin PB0 of the microcontroller U1 outputs a high level signal to the base of transistor Q1. The transistor Q1 is turned on. The fixing contact 3 of the switch of the relay LS4 is connected to the moving contact 5 of the switch of the relay LS4. Namely, the second inductor Lx is grounded. At the same time, the pin PB2 of the microcontroller U1 outputs a high level signal to the base of the transistor Q3. The transistor Q3 is turned on. The fixing contact 3 of the switch of the relay LS5 is connected to the moving contact 5 of the switch of the relay LS5. Namely, the power source P5V charges the capacitor C9. After a preset time (in the embodiment, the preset time is a charging time of the capacitor C9), the pin PB2 of the microcontroller U1 outputs a low level signal to the base of the transistor Q3. The transistor Q3 is turned off. The fixing contact 3 of the switch of the relay LS5 is connected to the moving contact 4 of the switch of the relay LS5. Namely, the second inductor Lx and the capacitor C9 compose an LC circuit. A frequency output from the LC circuit is processed by the comparators U2 and U3 and then is output to the pin PA0 of the microcontroller U1. Thus, the inductance of the second inductor Lx can be gained according to the formula:

$$Lx = \frac{1}{4 π \cdot {f}^{2} \cdot C 9} ,$$

where Lx stands for the inductance of the second inductor Lx, π stands for ratio of a circle's circumference to its diameter, f stands for the frequency received by the pin PA0 of the microcontroller U1, and C9 stands for the capacitance of the capacitor C9. In one embodiment, the capacitor C9 is a 1800 picofarad (pF) mica capacitor.

When the inductance of the first inductor Ls needs to be measured, the microcontroller U1 receives a second input signal from the keyboard 130, and the pin PB0 of the microcontroller U1 outputs a low level signal to the base of the transistor Q1. The transistor Q1 is turned off. The fixing contact 3 of the switch of the relay LS4 is connected to the moving contact 4 of the switch of the relay LS4. Namely, the first inductor Ls is grounded. At the same time, the pin PB2 of the microcontroller U1 outputs a high level signal to the base of the transistor Q3. The transistor Q3 is turned on. The fixing contact 3 of the switch of the relay LS5 is connected to the moving contact 5 of the switch of the relay LS5. Namely, the power source P5V charges the capacitor C9. After a preset time, the pin PB2 of the microcontroller U1 outputs a low level signal to the base of the transistor Q3. The transistor Q3 is turned off. The fixing contact 3 of the switch of the relay LS5 is connected to the moving contact 4 of the switch of the relay LS5. Namely, the first inductor Ls and the capacitor C9 compose an LC circuit. A frequency output from the LC circuit is processed by the comparators U2 and U3 and then is output to the pin PA0 of the microcontroller U1. Thus, the inductance of the second inductor Ls can be gained according to the formula:

$$Ls = \frac{1}{4 π \cdot {f}^{2} \cdot C 9} ,$$

where Ls stands for the inductance of the first inductor Ls, π stands for ratio of a circle's circumference to its diameter, f stands for the frequency received by the pin PA0 of the microcontroller U1, and C9 stands for the capacitance of the capacitor C9.

When a coupling inductance of the first and second inductors Ls and Lx being connected in parallel needs to be measured, the microcontroller U1 receives a third input signal from the keyboard 130, and the pin PB0 of the microcontroller U1 outputs a low level signal to the base of the transistor Q1 and the pin PB1 of the microcontroller U1 outputs a high level signal to the base of the transistor Q2. The transistor Q1 is turned off and the transistor Q2 is turned on. The fixing contact 3 and the moving contact 4 of the switch of the relay LS4 are connected. The fixing contact 3 and the moving contact 5 of the switch of the relay LS6 are connected. Namely, the first and second inductors Lx and Ls are connected in parallel. At the same time, the pin PB2 of the microcontroller U1 outputs a high level signal to the base of the transistor Q3. The transistor Q3 is turned on. The fixing contact 3 and the moving contact 5 of the switch of the relay LS5 are connected. Namely, the power source P5V charges the capacitor C9. After a preset time, the pin PB2 of the microcontroller U1 outputs a low level signal to the base of the transistor Q3. The transistor Q3 is turned off. The fixing contact 3 and the moving contact 4 of the switch of the relay LS5 are connected. Namely, the first and second inductors Ls and Lx are connected in parallel and then connected in parallel to the capacitor C9, to compose an LC circuit. A frequency of the LC circuit is processed by the comparators U2 and U3 and then is output to the pin PA0 of the microcontroller U1. Thus, the coupling inductance can be gained according to the following formula:

$$2 Lk = \frac{1}{4 π \cdot {f}^{2} \cdot C 9} ,$$

where 2Lk stands for the coupling inductance of the first and second inductors Ls and Lx being connected in parallel, π stands for ratio of a circle's circumference to its diameter, f stands for the frequency received by the pin PA0 of the microcontroller U1, and C9 stands for the capacitance of the capacitor C9. According to the character of the coupling inductance, the leak inductance of the first and second inductors Ls and Lx being connected in parallel is equal to a half of the coupling inductance. Namely, the leak inductance is equal to Lk.

The microcontroller U1 controls the display screen U5 to display the inductance of the first inductor Ls, the inductance of the second inductor Lx, and the leak inductance of the first and second inductors Ls and Lx being connected in parallel.

The measurement system 1 outputs control signals to the transistors Q1-Q3 through the microcontroller U1, to control the first inductor Ls or the second inductor Lx and the capacitor C9 to compose an LC circuit, to further determine the inductances of the first and second inductors Ls and Lx. At the same time, the microcontroller U1 also controls the first and second inductors Ls and Lx connected in parallel and the capacitor C9 to compose an LC circuit, to further determine the leak inductance of the first and second inductors Ls and Lx being connected in parallel.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A measurement system applicable to measure inductances of a first inductor and a second inductor, the measurement system comprising:
a control circuit;
a measurement circuit connected to the control circuit, wherein the measurement circuit comprises a first capacitor, the control circuit outputs control signals to control the first inductor or the second inductor and the first capacitor to compose a first LC circuit; the control circuit receives a frequency output from the first LC circuit and determines inductances of the first or second inductor according to the formula:
$$L = \frac{1}{4 π \cdot {f}^{2} \cdot C} ,$$
where L stands for the inductance of the first or second inductor, f stands for a frequency output from the LC circuit, g stands for ratio of a circle's circumference to its diameter, and C stands for the capacitance of the first capacitor; the control circuit also outputs control signals to control the first and second inductors to be connected in parallel and then connected in parallel to the first capacitor to compose a second LC circuit, the control circuit receives a frequency output from the second LC circuit and determines a coupling inductance of the first and second inductors being connected in parallel, a leak inductance of the first and second inductors connected in parallel is equal to a half of the coupling inductance; and
a display circuit connected to the control circuit, to display the inductance of the first inductor, the inductance of the second inductor, and the leak inductance.

2. The measurement system of claim 1, wherein the first capacitor is a 1800 picofarad (pF) mica capacitor.

3. The measurement system of claim 2, wherein the control circuit comprises a microcontroller, a first group of input output (I/O) pins of the microcontroller output control signals to the measurement circuit, a first pin of a second group of I/O pins of the microcontroller is connected to the measurement circuit, second to fourth pins of the second group of I/O pins are connected to a keyboard, a first power pin of the microcontroller is connected to a first power source through a first resistor and also connected to a cathode of a voltage regulating diode and a control terminal of the voltage regulating diode, an anode of the voltage regulating diode is grounded; the first power pin of the microcontroller is also connected to a second power source, second and third capacitors are connected in parallel between the anode and the control terminal of the voltage regulating diode; a second power pin of the microcontroller is connected to the first power source through an inductor, fourth and fifth capacitors are connected in parallel between the second power pin of the microcontroller and ground; a third group of I/O pins of the microcontroller are connected to the display circuit; a fourth group of I/O pins of the microcontroller are grounded through first to third switches, respectively; first and second clock pins of the microcontroller are respectively connected to two ends of a crystal oscillator, the two ends of the crystal oscillator are grounded respectively through sixth and seventh capacitors; a third power pin of the microcontroller is connected to the first power source; a reset pin of the microcontroller is connected to the first power source through a second resistor and also grounded through an eighth capacitor, a ninth capacitor is connected between the first power source and ground.

4. The measurement system of claim 3, wherein the measurement circuit comprises first to third transistors, first to third relays, and first and second comparators, a base of the first transistor is connected to a first pin of the first group of I/O pins of the microcontroller through a third resistor, an emitter of the first transistor is grounded, a collector of the first transistor is connected to a first end of the coil of the first relay and also connected to an anode of the first diode; a second end of the coil of the first relay is connected to a cathode of the first diode, the cathode of the first diode is also connected to the first power source through a fourth resistor, a fixing contact of the switch of the first relay is grounded, a first moving contact of the switch of the first relay is connected to the fixing contact of the switch of the third relay, a first moving contact of the switch of the third relay is grounded, a second moving contact of the switch of the third relay is connected to the second moving contact of the switch of the first relay; a base of the second transistor is connected to a second pin of the first group of I/O pins of the microcontroller through a fifth resistor, an emitter of the second transistor is grounded, a collector of the second transistor is connected to a first end of the coil of the third relay and also connected to an anode of the second diode, a second end of the coil of the third relay is connected to a cathode of the second diode, the cathode of the second diode is also connected to the first power source through a sixth resistor; a first moving contact of the switch of the first relay is connected a first end of the second inductor through the first inductor, a second end of the second inductor is connected to a second moving contact of the switch of the first relay; a base of the third transistor is connected to a third pin of the first group of I/O pins of the microcontroller through a seventh resistor, an emitter of the third transistor is grounded, a collector of the third transistor is connected to a first end of the coil of the second relay and also connected to an anode of the third diode; a second end of the coil of the second relay is connected to a cathode of the third diode, the cathode of the third diode is also connected to the first power source through an eighth resistor; a fixing contact of the switch of the second relay is grounded through the first capacitor, a first moving contact of the switch of the first relay is connected to the first end of the second inductor, a second moving contact of the switch of the second relay is connected to a non-inverting input terminal of the first comparator through ninth and tenth resistors in series, the non-inverting input terminal of the first comparator is connected to the first end of the second inductor through an eleventh capacitor, the non-inverting input terminal of the first comparator is grounded through an eleventh resistor; an inverting input terminal of the first comparator is grounded through a twelfth capacitor and also connected to an output terminal of the first comparator through a twelfth resistor; the output terminal of the first comparator is connected to the non-inverting input terminal of the first comparator through a thirteenth resistor and also connected to the first power source through a fourteenth resistor, a thirteenth capacitor is connected between the first power source and ground, a non-inverting input terminal of the second comparator is connected to the output terminal of the first comparator through a fifteenth resistor, an inverting input terminal of the second comparator is connected to an output terminal of the second comparator and the first pin of the first group of I/O pins of the microcontroller.

5. The measurement system of claim 4, wherein the display circuit comprises a display screen, a power pin of the display screen is connected to the first power source, first to fourth data pins of the display screen are respectively connected to a fourth pin, a third pin, a second pin, and a first pin of the third group of pins of the microcontroller, a ground pin of the display screen is grounded.
